(19) United States
(12) Patent Application Publication
(10) Pub. No.: US 2002/0002951 A1
(43) Pub. Date: Jan. 10, 2002

(54) HEATING INSTALLATION FOR A REACTOR

(76) Inventor: VLADIMIR IVANOVICH KUZNETSOV, DELFT (NL)

Correspondence Address: KNOBBE MARTENS OLSON & BEAR LLP, 620 NEWPORT CENTER DRIVE, SIXTEENTH FLOOR, NEWPORT BEACH, CA, 92660, US

(21) Appl. No.: 09/389,716

(22) Filed: Sep. 3, 1999

(51) Int. Cl. C23C 16/00

(52) U.S. Cl. 118/724

(57) ABSTRACT

Heating installation for a reactor. The reactor is provided with gas feed openings and gas discharge openings opening into a treatment chamber for accommodating a wafer floating therein. By means of such a treatment a wafer can be heated and cooled relatively rapidly. During the actual treatment it is important that the gas is heated sufficiently and to this end a heating installation is present. The latter consists of heating means, such as electrical heating means, arranged in a body which adjoins the reactor and in which channels have been made which connect into the gas feed openings and through which the treatment gas or other gas is fed.

### BACKGROUND OF THE INVENTION

The present invention relates to a reactor for treating a wafer at elevated temperature. Such a reactor is known from U.S. Pat. No. 5,595,606-A. A treatment device is disclosed therein for a wafer, wherein the wafer supports on a susceptor on one side and is provided with flow of treating gas on the other side. Heating of the wafer is effected with a lamp, functioning from the side of the susceptor. The wafer is heated to about 400° C. by the lamp. Heat from the wafer is radiated to the wall being at a considerable spacing and wherein openings are provided from which the gas flows. To prevent overheating of the wall a cooling circuit has been provided.

The treatment substance is liquid at relatively low temperature. Because this is undesirable at leaving the outflow openings, heating means are provided to heat the gas to about 100° C., such that it can be guaranteed that this heating substance at leaving the opening in the wall of the reactor is in gas phase.

From WO-96/17973 a treatment device is known for a wafer, wherein the susceptor for the wafer is heated with resistence heating. Gas flows from the opposite wall of the reactor through a numer of channels. In order to controll the temperature of the gas, and more particular to prevent overheating, a water based cooling is provided in a channel through which the gas flows.

EP-0.821.085 discloses a treatment device for a wafer, wherein the wafer is heated with a number of lamps being adjacent to each other. These lamps are spaced from the boundery with the treatment compartment. In the intermediate part a number of channels having outflow openings for a gas is realised. Radiation energy from the lamps goes through windows, delimiting the gas channels to outflow openings and hits the wafer to be treated. There is no suggestion about heating of the gas.

### SUMMARY OF THE INVENTION

Subject invention relates in particular, but not exclusively, to a device for floating treatment of wafers.

In such a case the reactor comprises an alongated treatment compartment for containing the wafer, wherein on both sides of the wafers in the reactor compartment gas feed openings are provided to maintain the wafer in position while also gas discharge openings are provided. However, the invention is not restricted to a reactor of this type, but can also be used with so-called ‘shower head’ systems, with which a stream of gas is passed over a wafer surface, tide wafer being supported in some way from the oilier side. The invention will be described below with reference to a reactor for the floating treatment of wafers. The floating treatment of wafers, with which contact-free heating takes place, has the advantage tat, in particular, rapid heating can be provided. It has been found that heating of the wafers essentially takes place by conduction of heat originating from the surrounding parts of the reactor chamber, the gas present acting as conducting medium. Heat transfer by radiation plays a minor role. This means that it is important that the gas supplied is at a temperature close to the final treatment temperature in order to be able to heat the wafers sufficiently rapidly and to be able to keep them at the treatment temperate. To this end it is proposed in the prior art to construct the feed line for the gas in the form of a pipe of appreciable length (6-7 metres) and to feed the gas through said pipe, after which it is fed via a distributor element to the various gas feed openings in the reactor. In the pipe the gas is, for example, heated from 20° C. to 1000° C. It will be understood that because of the relatively high temperature of the pipe special measures have to be taken in order to prevent contact with operators and to achieve insulation with respect to the surroundings. In view of the appreciable let, problems are associated with this. Because the gas has a temperature of, for example, about 1000° C. at the end of the pipe, the distributor element for distributing the gas over the various gas feed openings (tens to hundreds) must also be able to withstand the relatively high temperature. Moreover, such a distributor element must be gastight. This means that appreciable demands are also made in respect of the distributor element, as a result of which, overall, a gas feed device with the heating installation incorporated therein is expensive.

The aim of the present invention is to reduce the size of the heating installation and to lower the costs associated with the heating installation and gas feed.

This aim is achieved with a reactor for treating a wafer at elevated temperature, said reactor comprising a heating for heating said wafer, as well as a feed for gas for treatment of said wafer, said gas feed being provided in at least a wall of said reactor and comprising a number of channels provided in a body, said channels being heated by heating means provided in said body, wherein the heating for said wafer comprises said heating means.

In contrast in the prior art described above, the gas is used for heating of the wafer and no longer radiation energy is used for heating thereof. Heating of the gas is realised by heating of the channel wherein the gas is moved. Such heating will be realised by conduction/convection.

Heating of this type in a separate body or block arranged mounted on the reactor must be differentiated from the heating of the reactor itself. Such heating for the actual reactor using electrical resistance elements is generally known in the prior art, but said heating is not capable of heating gas which, for example, enters at 20° C. to approximately 1000° C. To this end it is necessary to use the bodies or blocks described above in which the channels have been made. As a result of the construction according to the invention, a long pipe at high temperature is no longer necessary and the distributor element is no longer subjected to high temperatures, as a result of which the demands in respect of the construction thereof are appreciably less stringent.

Although it is possible that the number of channels can be less than he number of openings, that is to say that further splitting occurs downstream of the channels, according to an advantageous embodiment the number of channels is essentially equal to the number of gas feed openings. The heating means can extend both in and around the body in order to provide optimum heat transfer to the channels. It will be understood that the length of the channels, the flow rate of the gas through the channels and the rise in temperature of the gas that flows through the channels are dependent on one another and on the amount of energy supplied via the electrical heating means. Surprisingly, it has been found that for the above example in which a rise in temperature of, for example, approximately 1000° C. is necessary, the thickness of such a block or body can be approximately 3 cm. The thickness of the material in which the openings of the reactor extend is naturally in addition to this, but this makes little or no contribution to heating of the gas passing through it. The length of the channels, that is to say the thickness of the body, is also dependent on the number of channels in the plate for a specific flow rate. That is to say, when a specific flow rate is kept constant, the height of the body can be approximately halved by doubling the number of channels. The power supplied can be relatively limited. If approximately 20 slm has to be heated from 20 to 1000° C., a power of less than 1 kW and more particularly 0.5 kW can suffice.

Moreover, the gas stream is stabilised by the presence of the channels.

It has been indicated above that the heating means can be electrical heating means. It will be understood that any other medium can be used to transfer thermal energy to the gas.

The reactor according to the prior art was provided with insulation around the treatment chamber. According to an advantageous embodiment of the present invention, such insulation is now placed outside the assembly comprising the block or body and the reactor.

The reactors described above can be used for any treatment of the wafer, such as annealing and oxidation.

According to a further aspect the invention relates to the treatment of a wafer in a reactor wherein the wafer is subjected to a gas flow from at least one of the walls of said reactor, wherein heating of the wafer is substantially realised by gas flowing from said openings. This gas is first heated during passing of the channels adjacent to the wall of the reactor before flowing from said openings. If the wafer is at an (initial) lower temperature than the wall of the reactor after leaving the openings, the gas will transfer a part of its heat to the wafer. After that the gas is reheated by conduction of heat from the wall of the reactor.

### DETAILED DESCRIPTION OF THE DRAWINGS AND PREFERRED EMBODIMENT

The invention will be explained in more detail below which reference to an illustrative embodiment shown in the drawing. In the drawing the only figure shows, diagrammatically, a cross-sectional view of a reactor provided with the heating installation according to the invention.

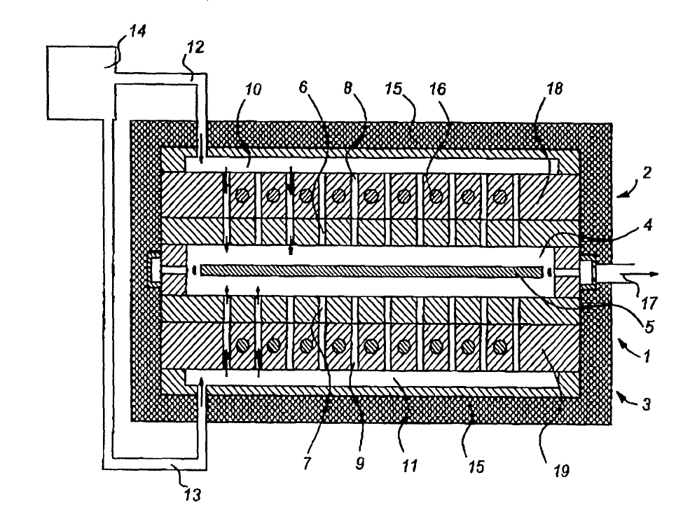

A reactor in which floating treatment of wafers can be carried out is indicated by 1. It will be understood that the invention is applicable to any reactor to which relatively appreciable quantities of gas have to be fed, on the one hand in order to treat the wafer concerned and on the other hand in order to hold such a wafer in the floating position. The wafer concerned is indicated by 5 in FIG. 1 and is accommodated in treatment chamber 4, which is delimited between the top 2 and bottom 3 of the reactor 1. The various dimensions have not been drawn to scale. For instance, the distance between the wafer and the edge of the treatment chamber is very much smaller than is shown.

Both the top and the bottom are provided with openings 6 and 7, respectively, for supplying gas. This gas is discharged via openings 17, which can be arranged around the periphery of the treatment chamber 4 and open, in a manner which is not shown in more detail, into an annular channel provided with a further discharge.

The reactor is provided on both the top and the bottom with adjoining blocks 18, 19. Channels 8, 9, respectively, have been made in said blocks 18, 19, which channels communicate with distribution chambers 10 and 11, respectively, which are connected via lines 12 and 13, respectively, to a gas supply or gas source 14. The channels have a diameter of, for example, 1 mm. Electrical heating elements 16, each having a total power of approximately 0.5 kW, have been fitted in the blocks 18, 19. It will be understood that the heating elements are controlled, in a manner which is not shown in more detail, such that the desired heating of the gases is obtained.

In the subject example, the blocks are approximately 3 cm high, while the openings likewise have a height of approximately 3 cm. It has been found that with the heating elements described above heating of supplied gas from 20 to 1000° C. is possible with the feed of approximately 20 slm per block. Insulation 15 is fitted around the blocks concerned. Approximately 60 channels have been made in the blocks, which channels open into 60 openings 6 and 7, respectively. The installation described above is particularly suitable for annealing and oxidation. Treatment of the wafer is realised at a considerable elevated temperature of at least 400° C. preferably 700° C. and more particular 1000° C.

If the wafer is received in a so called floating wafer reactor, the spacing between the wafer and the most adjacent wall of the reactor is about 0,1 mm.

Although the invention has been described above with reference to a preferred embodiment, it will be understood that numerous modifications can be made without going beyond the scope of the invention as described in the appended claims. For instance, it is possible to vary the number of channels and the diameter thereof depending on the desired gas flow rate and heating of the gas supplied. It is also possible to introduce differences between the top block 18 and bottom block 19.

1. A reactor for treating a wafer at elevated temperature, said reactor comprising a heating for heating said wafer, as well as a feed for gas for treatment of said wafer, said gas feed being provided in at least a wall of said reactor and comprising a number of channels provided in a body, said channels being heated by heating means provided in said body, wherein the heating for said wafer comprises said heating means.

2. A reactor according to claim 1, comprising a floating wafer reactor, wherein between two opposite walls of said reactor a treating compartment is delimited and each of said walls is provided with gas discharge openings.

3. A reactor according to claim 1, wherein said heating means (16) extend around said body.

4. A reactor according to claim 1, wherein said heating means comprise electrical heating means.

5. A reactor according to claim 1, wherein said reactor is provided with thermal insulation and said body is arranged between said insulation and said treatment chamber.

6. A reactor according to claim 2 comprising an elongated treatment chamber and is provided on the long side of said treatment chamber with gas feed openings and is provided with gas discharge openings.

7. Method for treating of a wafer in a reactor, said wafer being subjected to a gas flow from at least one of the wall of said reactor, wherein the wafer is heated and wherein gas flowing the openings in said wall is heated in channel extending in a body adjacent to said wall, characterised in that said wafer is substantially heated by gas flowing from said openings.

8. Method according to claim 7, wherein the outflow temperature of said gas is at least 600° C.

9. Method according to claim 7, wherein said wafer is floatingly received between two opposite walls of a reactor, wherein the spacing between each of said walls and the wafer is between 0,05 and 1 mm.
